(19) United States
(12) Patent Application Publication
(10) Pub. No.: US 2014/0015817 A1
(43) Pub. Date: Jan. 16, 2014

(54) INFORMATION DISPLAY DEVICE

(71) Applicant: Panasonic Corporation, Osaka (JP)

(72) Inventors: Suguru Nakao, Hyogo (JP); Shuji Yamashita, Nara (JP); Takehiko Yamashita, Hyogo (JP)

(21) Appl. No.: 13/932,248

(22) Filed: Jul. 1, 2013

Related U.S. Application Data
(63) Continuation of application No. PCT/JP2013/000502, filed on Jan. 30, 2013.

(30) Foreign Application Priority Data
Jul. 10, 2012 (JP) 2012-154258

(51) Int. Cl. H05K 5/00

(52) U.S. Cl. CPC H05K 5/0017
USPC 345/205; 345/87

(57) ABSTRACT

An information display device includes: a display unit including a display panel and a drive circuit portion, arranged on a back side of the display panel, for displaying information on the display panel; and a front panel arranged on a display surface side of the display panel and larger than an outside dimension of the display panel. The front panel has a shape in which curves are formed in corner portions at four corners thereof. A long decoration member having flexibility is arranged in a winding manner so as to cover an entirety of outer peripheral surfaces of four sides of the display unit including an outer peripheral surface of the front panel. The decoration member includes an adhesive layer bonded to the outer peripheral surface of the display unit such that the decoration member is in close contact with the outer peripheral surface of the front panel.

### BACKGROUND

1. Field

The present technology relates to an information display device for use in an AV apparatus typified by a plasma television, a tablet type information terminal having an input means such as a touch panel, or the like.

2. Description of the Related Art

In recent years, plasma televisions and liquid crystal televisions that employ a so-called narrow-frame design in which the bezel width is decreased, have been mainstream. For example, televisions of a glass full-flat design have been popularized in which a front panel made of glass is arranged in front of a display panel such that a frame-like casing is not seen from the front. In addition, in a tablet type information terminal having an input means such as a touch panel, an information display device in which a front glass having a pressure-sensitive or electrostatic capacitance type touch panel function is arranged in front of a display panel, occupies the majority of the information terminal.

Such a front panel made of glass is easily broken when a shock is applied to, particularly, an end surface thereof. Thus, the front panel has a structure in which the end surface of the glass is protected by a metallic frame. The frame has a structure obtained by combining extruded members made of aluminum as four sides, or a structure obtained by press-molding in which a center portion of a plate of aluminum larger in size than the front panel is punched. In addition, a tablet type information terminal having a small screen has a structure in which a member formed by die-casting or machining of aluminum is used as a casing and a front panel made of glass is fixed to the casing.

However, the structure obtained by combining the extruded members made of aluminum as four sides has a problem that the joint between each extruded member is seen at each corner portion and thus the design property is deteriorated; and weight increase and cost increase are caused. In addition, the structure obtained by press-molding in which the center portion of the plate of aluminum is punched has a problem that the stock utilization is low and further cost increase is caused.

Meanwhile, Japanese Laid-Open Patent Publication No. 2000-295544 discloses a structure in which a cushioning material is added around a display device, thereby absorbing shocks.

The present technology has been made in view of such circumstances and provides an information display device that is safe and ensures a desired design property and desired strength without causing weight increase and cost increase in order to protect a front panel made of glass.

### SUMMARY

In one general aspect, the present technology provides an information display device including: a display unit including a display panel and a drive circuit portion, arranged on a back side that is a side opposite to a direction in which information is displayed on the display panel, for displaying the information on the display panel; a back cover arranged so as to cover a drive circuit portion side of the display unit; and a front panel arranged on a display surface side on which the information is displayed on the display panel of the display unit, the front panel being larger than an outside dimension of the display panel. The front panel has a shape in which a curve is formed in each of corner portions at four corners thereof. A decoration member having flexibility and a long length is arranged in a winding manner so as to cover an entirety of outer peripheral surfaces of four sides of the display unit including an outer peripheral surface of the front panel. The decoration member includes an adhesive layer that is bonded to the outer peripheral surface of the display unit such that the decoration member is in close contact with the outer peripheral surface of the front panel.

According to the present technology, it is possible to provide an information display device that is safe and ensures a desired design property and desired strength without causing weight increase and cost increase in order to protect a front panel made of glass.

### BRIEF DESCRIPTION OF THE DRAWINGS

FIG. 1 is a perspective view showing the appearance of a liquid crystal television according to one embodiment;

FIG. 2 is a cross-sectional view taken along the A-A line in FIG. 1;

FIG. 3 is a plan view showing the appearance of an upper corner portion of the liquid crystal television shown in FIG. 1;

FIG. 4 is a cross-sectional view of another embodiment, taken along the A-A line in FIG. 1; and

FIG. 5 is a perspective view showing the appearance of a tablet type information terminal as an example of an information display device according to another embodiment.

### DETAILED DESCRIPTION

Hereinafter, as an example of disclosure of an information display device according to the present technology, a liquid crystal display device applied to a liquid crystal television will be described with reference to the drawings. However, there will be instances in which detailed description beyond what is necessary is omitted. For example, detailed description of subject matter that is previously well-known, as well as redundant description of components that are substantially the same will in some cases be omitted. This is to prevent the following description from being unnecessarily lengthy, in order to facilitate understanding by a person of ordinary skill in the art.

The inventors provide the following description and the accompanying drawings in order to allow a person of ordinary skill in the art to sufficiently understand the present disclosure, and the description and the drawings are not intended to restrict the subject matter of the scope of the patent claims.

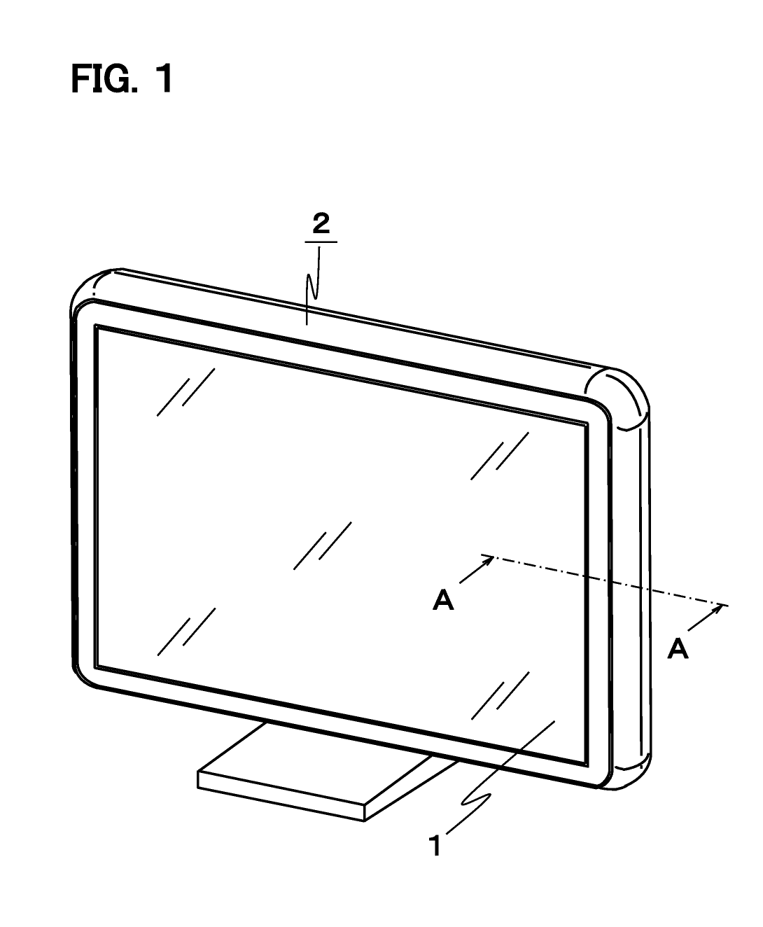

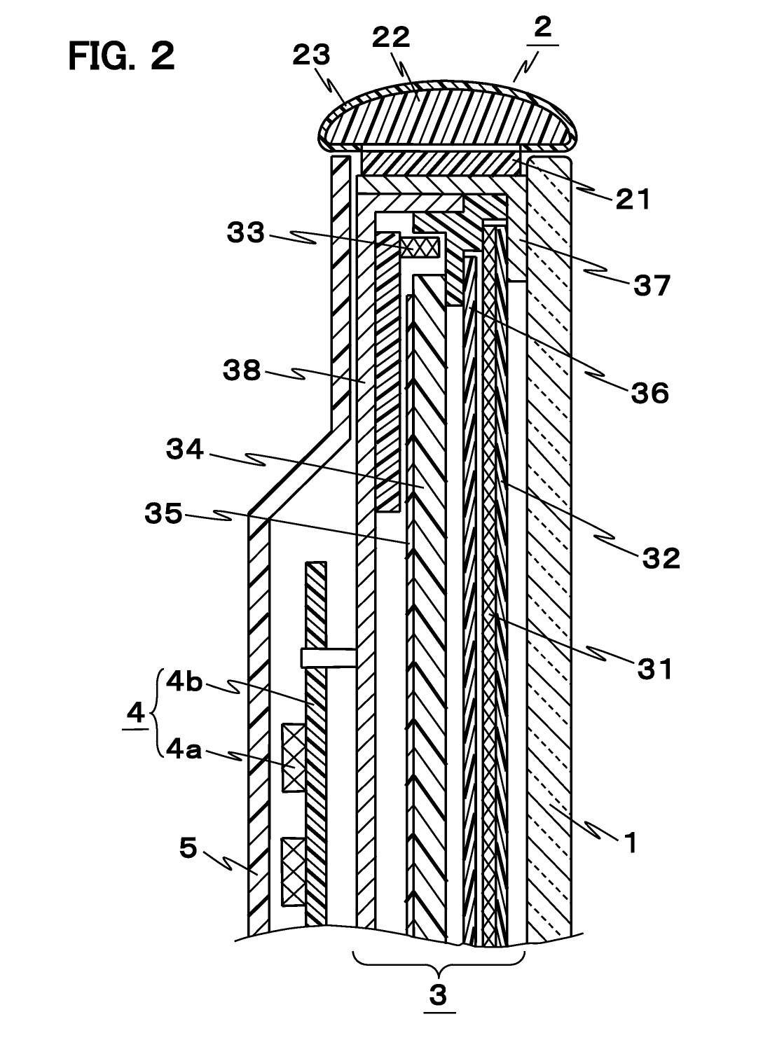

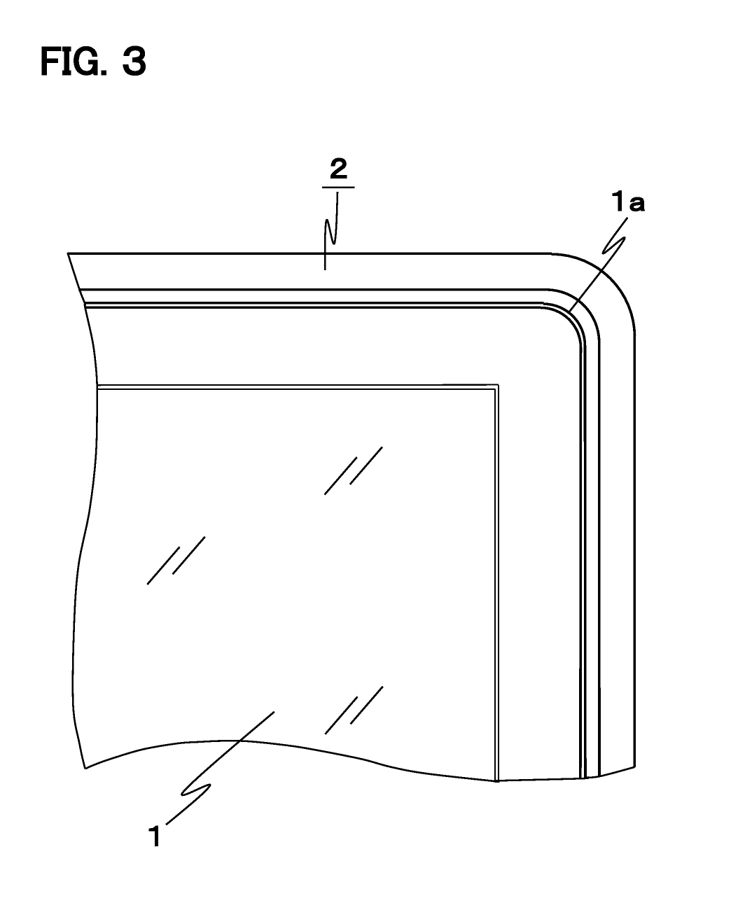

FIG. 1 is a perspective view showing the appearance of a liquid crystal television as an example of an information display device according to one embodiment of the present technology. FIG. 2 is a cross-sectional view taken along the A-A line in FIG. 1. FIG. 3 is a plan view showing the appearance of an upper corner portion of the liquid crystal television shown in FIG. 1.

As shown in FIG. 1, in the liquid crystal television according to the present embodiment, a decoration member 2 having flexibility and a long length is arranged in a winding manner so as to cover the entirety of the outer peripheral surface of a front panel 1 as described later.

As shown in FIG. 2, a display unit includes a liquid crystal panel portion 3 that is a display panel, and a drive circuit portion 4 for displaying information on the liquid crystal panel portion 3. It should be noted that the drive circuit portion 4 is arranged on a back side that is a side of the liquid crystal panel portion 3 that is opposite to the front panel 1. The liquid crystal panel portion 3 includes a liquid crystal panel 31, a polarizing plate 32, an LED 33 constituting a backlight, a light guide plate 34, a reflective plate 35, a diffusion plate 36, a metallic upper frame 37 and a metallic lower frame 38 storing these components, and the like. The drive circuit portion 4 includes an electronic component 4a that drives the LED 33 and liquid crystal of the liquid crystal panel 31, and a printed wiring board 4b on which the electronic component 4a is mounted. The drive circuit portion 4 is attached to the lower frame 38 of the liquid crystal panel portion 3 by means of screws or the like.

In addition, a back cover 5 is arranged so as to cover the drive circuit portion 4 side of the display unit and is attached to the lower frame 38 of the liquid crystal panel portion 3.

The front panel 1 made of glass is arranged on a display surface side of the liquid crystal panel portion 3 of the display unit and has a quadrangular shape larger than the outside dimension of the liquid crystal panel 31. Furthermore, as shown in FIG. 3, the front panel 1 has a shape in which a curve la is formed in each of corner portions at four corners thereof by using the decoration member 2. It should be noted that FIG. 3 shows only the appearance of the upper corner portion of the liquid crystal television shown in FIG. 1.

The decoration member 2 is arranged so as to cover the outer peripheral surface of the front panel 1 and the entirety of the outer peripheral surfaces of four sides of the display unit. In addition, the decoration member 2 is bonded to the outer peripheral surface of the upper frame 37 of the liquid crystal panel portion 3 via an adhesive layer 21 so as to be in close contact with the outer peripheral surface of the front panel 1. In the decoration member 2, the dimension on the liquid crystal panel 31 side (hereinafter, referred to as back side) on which the adhesive layer 21 is provided is the largest in a cross-sectional shape in a direction perpendicular to the surface of the front panel 1. In other words, the decoration member 2 has such a curved shape that the thickness thereof is decreased with increasing distance from the center of the decoration member 2 in the thickness direction of the liquid crystal panel 31. Due to such a shape, when the decoration member 2 is bent at the four corners of the front panel 1, a wrinkle is unlikely to occur on the surface of the decoration member 2. It should be noted that the cross-sectional shape of the decoration member 2 is a curved surface shape in the present embodiment, but may be a triangle shape, a trapezoid shape, or the like.

Furthermore, the adhesive layer 21 at the back surface of the decoration member 2 is formed from an expanded resin material obtained by expanding an epoxy-based or acrylic-based resin such that a sufficient thickness is ensured. In addition, the adhesive layer 21 is bonded to the outer peripheral surface of the display unit (i.e., the front panel 1, the liquid crystal panel portion 3, and the back cover 5) by means of pressure welding such that the decoration member 2 is in close contact with the outer peripheral surface of the front panel 1. In the corner portions at the four corners of the display unit, the adhesive layer 21 is compressed and the decoration member 2 is bent and bonded along the curves la in the four corners of the front panel 1. Therefore, the decoration member 2 is arranged on the entire periphery of the front panel 1 along the outer peripheral surface of the front panel 1 so as to cover the end surface of the glass.

Moreover, the decoration member 2 has flexibility in shape in a temperature range equal to or higher than the glass transition point, and a base 22 arranged at a center portion of the decoration member 2 is formed from a resin material that cures at normal temperature. With the resin material, after the decoration member 2 is heated to a temperature higher than the glass transition point and softened, it is possible to bend the decoration member 2 along the curves 1a at the four corners of the front panel 1. It should be noted that when the temperature of the base 22 reaches normal temperature, the base 22 becomes hard to such an extent that a shock applied unexpectedly to the display unit is absorbed, and thus the base 22 is allowed to have ability to absorb shocks.

Furthermore, a urethane-based or acrylic-based resin material is used as the basic material of the base 22 of the decoration member 2. In addition, a film subjected to conductive treatment is attached to the surface of the base 22. In other words, the base 22 is formed by coextrusion molding in which, when the basic material is extruded into a long shape, a film 23 having a metal layer obtained by coating a polyester-based or fluorine-based resin film with a conductive material such as silver or aluminum in form of a thin film by vapor deposition or sputtering is attached to the extruded basic material by means of an adhesive. Therefore, the surface of the decoration member 2 has metallic luster, and thus it is possible to realize a design property that provides style to the liquid crystal television.

As described above, the liquid crystal television according to the present embodiment has a configuration in which the decoration member 2 is pressure-welded to the outer peripheral surface of the display unit (the front panel 1, the liquid crystal panel portion, and the back cover 5). In addition, in the decoration member 2, no frame joint occurs in the corner portions of the display unit. Thus, unlike a conventional structure in which the end surface of glass is protected by a metallic frame having high rigidity, the liquid crystal television is safe, for example, even when the liquid crystal television is lifted or even when a person collides against the liquid crystal television. In addition, since the decoration member 2 is formed from the expanded resin material, the decoration member 2 has high ability to absorb shocks, for example, when the decoration member 2 comes into contact with foreign matter, and further the decoration member 2 is lightweight. Therefore, with the liquid crystal television according to the present embodiment, it is possible to realize prevention of breakage of the glass, a desired design property, safety, and weight reduction at low cost.

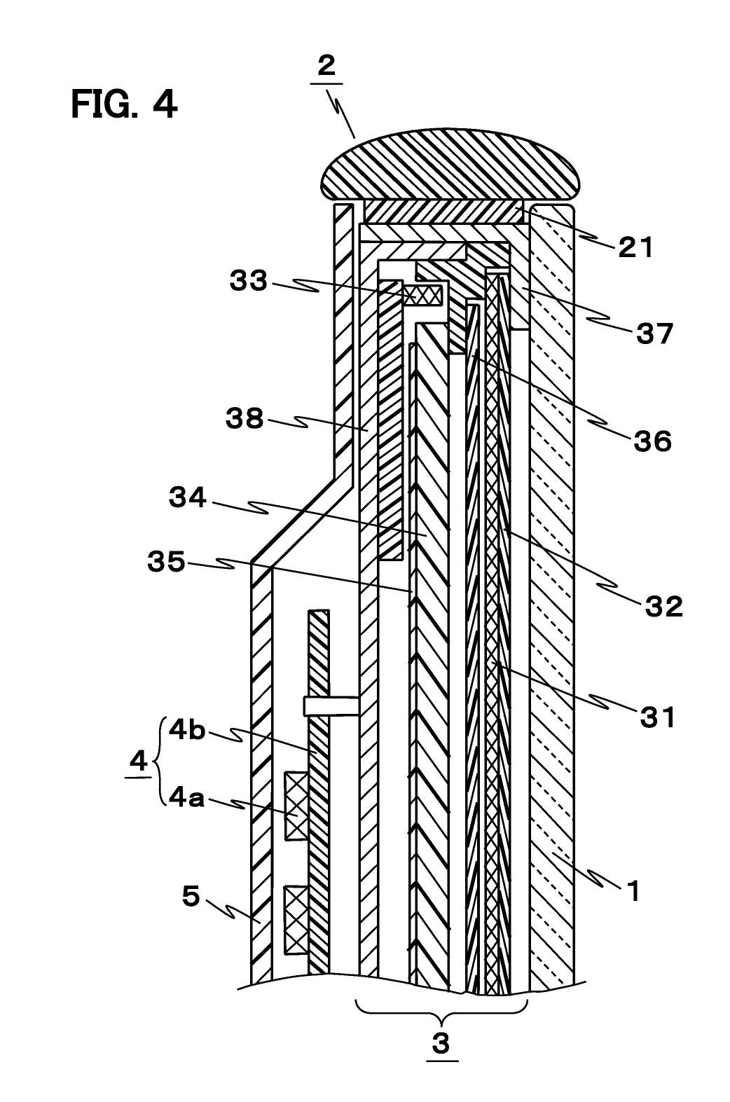

FIG. 4 shows the configuration of a liquid crystal television according to another embodiment. It should be noted that FIG. 4 is a cross-sectional view taken along the A-A line in FIG. 1. In addition, in the liquid crystal television according to the present embodiment, the components having the same functions as those of the liquid crystal television according to the above-described embodiment are designated by the same reference characters.

A decoration member 2 according to the present embodiment is a composite material obtained by blending metal powder with the above-described resin material and conducting molding. Specifically, a base material obtained by blending a metallic pigment such as a filler of silver or aluminum with a urethane-based or acrylic-based resin material is molded, for example, by means of extrusion molding. When the extrusion molding is conducted, the metallic pigment appears on the surface of a molded product, and thus the decoration member 2 has a metallic appearance. Thus, the decoration member 2 according to the present embodiment eliminates the necessity of a process of coating the surface thereof with a film having a metallic appearance and is allowed to have a metallic appearance. It should be noted that the resin material used for the decoration member 2 has viscoelasticity, and thus it is possible to provide ability to absorb shocks, to the display unit, and it is possible to realize safety and weight reduction at low cost.

It should be noted that the liquid crystal television has been described in the above embodiment, but is an example. The present technology is also applicable to, for example, not only the display device portion of a portable DVD player or a camera but also the casing of a stationary electronic apparatus such as a portable optical disc drive or an optical disc recorder.

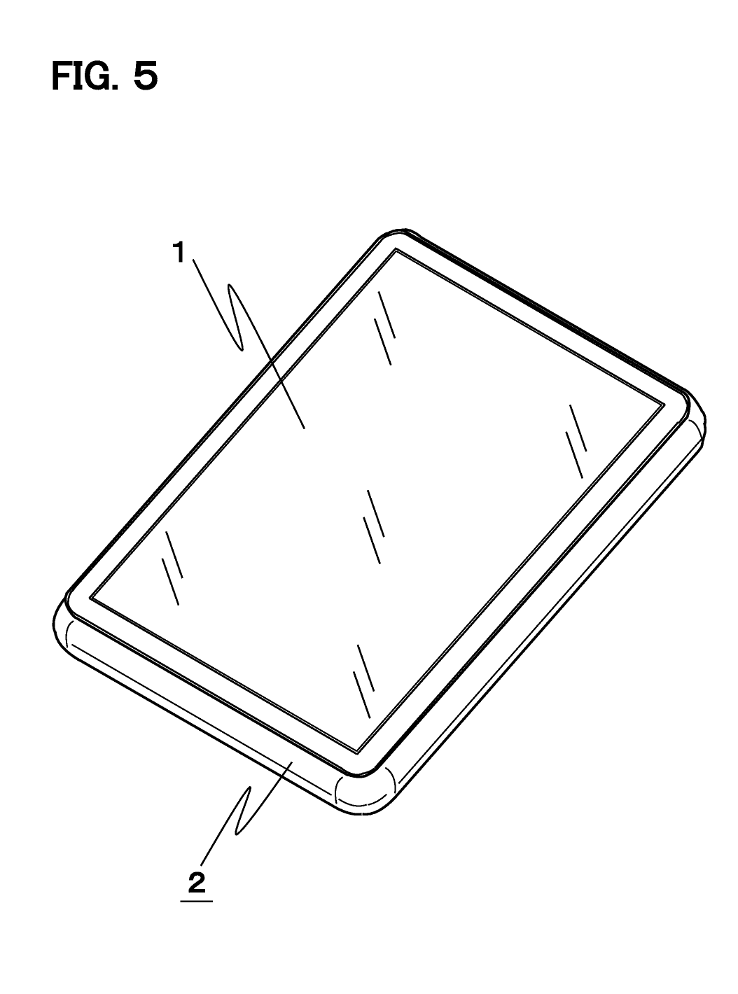

FIG. 5 is a perspective view showing the appearance of a tablet type information terminal as an example of an information display device according to another embodiment of the present technology. It should be noted that in the present embodiment, a front panel 1 of the tablet type information terminal has a contact type touch panel function. In addition, the internal structure of a display unit is the same as the structure described in the above-described embodiment.

The tablet type information terminal according to the present embodiment is operated mainly in a state where the user holds the tablet type information terminal with their hands. Thus, the tablet type information terminal is allowed to meet a demand for weight reduction and safety of the apparatus, as described above. In addition, the decoration member 2 is allowed to provide a preferable design property to the tablet type information terminal at low cost.

It should be noted that the tablet type information terminal has been described in the present embodiment, but is an example. The present technology is also applicable to, for example, a mobile phone or the like.

As presented above, the embodiments have been described as an example of the technology according to the present disclosure. For this purpose, the accompanying drawings and the detailed description are provided.

Therefore, components in the accompanying drawings and the detail description may include not only components essential for solving problems, but also components that are provided to illustrate the above described technology and are not essential for solving problems. Therefore, such inessential components should not be readily construed as being essential based on the fact that such inessential components are shown in the accompanying drawings or mentioned in the detailed description.

Further, the above described embodiments have been described to exemplify the technology according to the present disclosure, and therefore, various modifications, replacements, additions, and omissions may be made within the scope of the claims and the scope of the equivalents thereof.

As described above, the information display device according to the present technology is applicable to improvement in the performance of the casing structure of, for example, a liquid crystal television, a plasma television, a tablet type information terminal, a laptop type information terminal, a mobile phone, a portable DVD player, a camera, an optical disc drive, an optical disc recorder, or the like.

What is claimed is:

1. An information display device comprising:
a display unit including a display panel and a drive circuit portion, arranged on a back side that is a side opposite to a direction in which information is displayed on the display panel, for displaying the information on the display panel;
a back cover arranged so as to cover a drive circuit portion side of the display unit; and
a front panel arranged on a display surface side on which the information is displayed on the display panel of the display unit, the front panel being larger than an outside dimension of the display panel, wherein
the front panel has a shape in which a curve is formed in each of corner portions at four corners thereof,
a decoration member having flexibility and a long length is arranged in a winding manner so as to cover an entirety of outer peripheral surfaces of four sides of the display unit including an outer peripheral surface of the front panel, and
the decoration member includes an adhesive layer that is bonded to the outer peripheral surface of the display unit such that the decoration member is in close contact with the outer peripheral surface of the front panel.

2. The information display device according to claim 1, wherein the decoration member is formed such that a dimension on the display panel side on which the adhesive layer is provided is the largest in a cross-sectional shape in a direction perpendicular to a surface of the front panel.

3. The information display device according to claim 1, wherein the adhesive layer of the decoration member is formed from an expanded resin material and is bonded to the outer peripheral surface of the display unit by means of pressure welding such that the decoration member is in close contact with the outer peripheral surface of the front panel.

4. The information display device according to claim 3, wherein the decoration member is formed by blending metal powder with the resin material and conducting molding.

5. The information display device according to claim 3, wherein the decoration member is one in which a metal layer is formed on a surface of the resin material.

6. The information display device according to claim 1, wherein the decoration member has flexibility in shape in a temperature range equal to or higher than a glass transition point and is formed from a resin material that cures at normal temperature.

7. The information display device according to claim 1, wherein the front panel has a contact type touch panel function.
